(19) United States
(12) Patent Application Publication
(10) Pub. No.: US 2012/0306067 A1
(43) Pub. Date: Dec. 6, 2012

(54) Thermally Enhanced Integrated Circuit Package

(75) Inventors: Pei-Haw Tsao, Tai-Chung (TW); Kuo-Chin Chang, Chiayi City (TW); Han-Ping Pu, Taichung (TW)

(73) Assignee: Taiwan Semiconductor Manufacturing Company, Ltd., Hsin-Chu (TW)

(21) Appl. No.: 13/151,720

(22) Filed: Jun. 2, 2011

(51) Int. Cl. H01L 23/488; H01L 23/36; H01L 21/50

(52) U.S. Cl. 257/692; 438/118; 257/713; 257/E23.023; 257/E23.101; 257/E21.499

(57) ABSTRACT

According to an embodiment, an integrated circuit package comprises a chip, a thermal component, and a molding compound. The chip comprises an active surface and a backside surface opposite the active surface. The thermal component is physically coupled to the backside surface of the chip. The molding compound encapsulates the chip, and an exposed surface of the thermal component is exposed through the molding compound. Another embodiment is a method to form an integrated circuit package.

### BACKGROUND

Since the development of the integrated circuit, the semiconductor industry has experienced continued rapid growth due to continuous improvements in the integration density of various electronic components (i.e., transistors, diodes, resistors, capacitors, etc.). For the most part, this improvement in integration density has come from repeated reductions in minimum feature size, which allows more components to be integrated into a given area. In turn, the increased density has allowed for smaller integrated circuit chips.

As a result of the increased density in the integrated circuit chips, there has been a need for dynamic solutions in packaging to allow for more connections to components exterior to the chip and to accommodate smaller chip sizes. One packaging technique has generally been known as an embedded wafer level ball grid array (eWLB) package. The eWLB package generally meets these needs for addition external connections and to accommodate smaller chip sizes plus has other advantages.

A chip in an eWLB package may overheat from time to time which may cause damage to the chip. One previous method to attempt to prevent the overheating was to add an external heat spreader. This approach has not had much success because of features inherent in the eWLB package. Another approach is to use heat dissipation kits, such as a fan, in a product in which the eWLB package is used. However, this approach may not be suitable for high performance hand-held products with no space for the heat dissipation kit.

Accordingly, there is a need in the art for enhanced thermal performance of an eWLB package.

### BRIEF DESCRIPTION OF THE DRAWINGS

For a more complete understanding of the present embodiments, and the advantages thereof, reference is now made to the following descriptions taken in conjunction with the accompanying drawings, in which:

FIGS. 1-9 are a process for manufacturing an integrated circuit package according to an embodiment; and

FIG. 10 is an integrated circuit package according to an embodiment.

### DETAILED DESCRIPTION OF ILLUSTRATIVE EMBODIMENTS

The making and using of the present embodiments are discussed in detail below. It should be appreciated, however, that the present disclosure provides many applicable inventive concepts that can be embodied in a wide variety of specific contexts. The specific embodiments discussed are merely illustrative of specific ways to make and use the disclosed subject matter, and do not limit the scope of the different embodiments.

Embodiments will be described with respect to a specific context, namely an embedded wafer level ball grid array (eWLB) package and methods for manufacturing an eWLB package. Other embodiments may also be applied, however, to other integrated circuit packages and methods of packaging.

In FIG. 1, a carrier substrate 2 is provided with a lamination foil 4 on a top surface of the carrier substrate 2. The lamination foil 4 may be any acceptable adhesive tape and may be placed on the carrier substrate 2 using a lamination tool. More particularly, the lamination foil 4 may be any acceptable adhesive tape that allows subsequent debonding of the carrier substrate 2 from molding compound and chips by, for example, a heat or ultra-violet (UV) treatment. An exemplary carrier substrate 2 includes a glass substrate, silicon, quartz, the like, or a combination thereof. An exemplary lamination foil 4 includes epoxy, resin, the like, or a combination thereof.

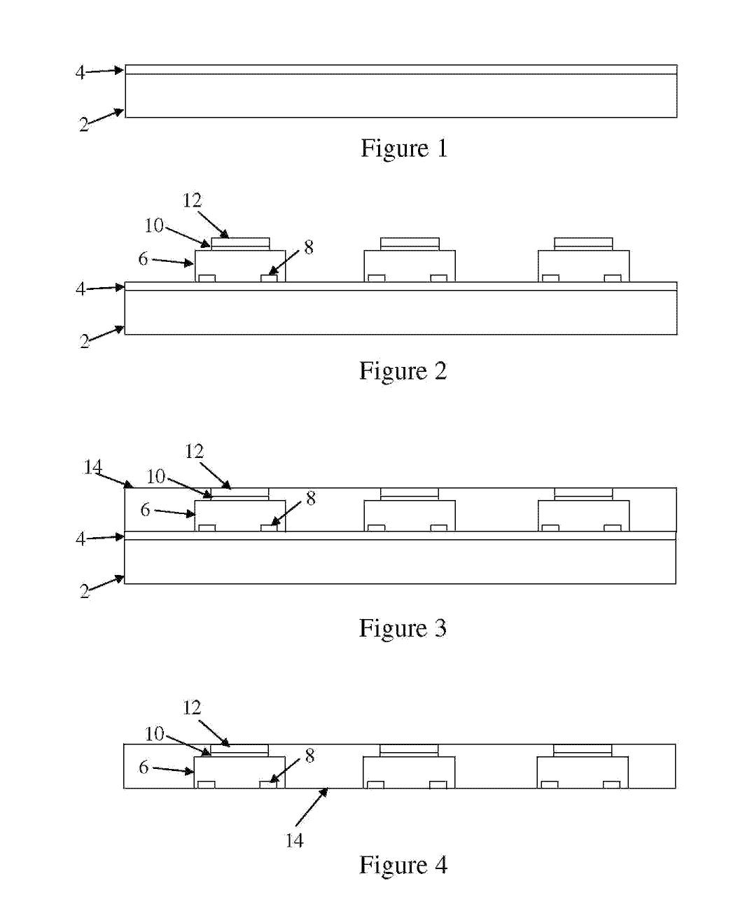

Referring to FIG. 2, known good chips 6 are placed on the lamination foil 4 and the carrier substrate 2. The lamination foil 4 adheres the chips 6 to the carrier substrate 2. Generally, chips 6 are processed from another wafer (not shown) through the formation of bond pads 8 on the chips 6. The chips 6 are then diced and tested. Known good chips 6 are then placed on the lamination foil 4 using, for example, an acceptable pick-and-place tool with the active surface of each chip, the active surface comprising bond pads 8, adhering to the lamination foil 4. The placement of the chips 6 on the carrier substrate 2 allows for a reconfiguration of the chips 6 from the originally processed wafer such that more area will subsequently be available for the formation of a ball grid array, as will be discussed in more detail below. Further, by using known good chips 6 after testing, packaging of faulty chips may be avoided to reduce manufacturing costs. Subsequent figures herein may use singular terms when referencing components in the figures; however, the steps may be applied to multiple components, such as to all the chips 6, even though singular terms are employed.

Continuing with FIG. 2, an adhesive film 10 is formed on the backside surface of the chip 6, e.g., the surface of the chip 6 that is opposite the active surface comprising the bond pads 8. The adhesive film 10 may be an epoxy, resin, the like, or a combination thereof. The thickness of the adhesive film 10 in a direction perpendicular to the backside surface may be between about 25 micrometers and about 100 micrometers. Although embodiments are not limited to a particular thickness, the thickness should not be so thick as to suppress thermal dissipation. A thermal component 12 is then adhered to the chip 6 by the adhesive film 10. The thermal component 12 may be a metal plate or a dummy semiconductor chip. Exemplary materials for the metal plate are copper, nickel plated copper, aluminum, the like, or a combination thereof. An exemplary dummy semiconductor chip may be the same or different material as the wafer processed to form the chip 6, such as a silicon chip, germanium chip, silicon germanium chip, quartz, the like, or a combination thereof. The thermal component 12 generally may have good thermal conductivity and/or have a coefficient of thermal expansion (CTE) comparable to the CTE of the chip 6. The thermal component 12 typically dissipates heat when in the completed package.

In one embodiment, the adhesive film 10 is formed on the backside surface of the chip 6 by depositing the adhesive film 10 on the chip 6 with a proper dispensing amount and pattern. The deposition of the adhesive film may be a film laminator. The placement of the thermal component 12 may be by a pick-and-place tool.

In another embodiment, the adhesive film 10 is pre-formed on the thermal component 12, such as before each thermal component 12 is singulated. The thermal component 12 and the adhesive film 10 are then placed on the backside of the chip 6 by, for example, a pick-and-place tool. Using a pre-formed adhesive film 10 may be desirable to better control the thickness of the adhesive film 10.

With reference to FIG. 3, a molding compound 14 is applied to the structure. In an embodiment, the molding compound is a different material from the thermal component 12. A method to spread the molding compound 14 to encapsulate the chips 6, such as compression molding, is used. The molding compound 14 is then cured. The resulting structure has a backside surface of the molding compound 14 that is co-planar with an exposed surface of the thermal component 12. The thickness of the molding compound 14 generally corresponds to the thickness of the combination of one chip 6, one adhesive film 10, and one thermal component 12 such that the thickness from the lamination foil 4 to the backside of the molding compound 14 and/or the exposed surface of the thermal component 12 is uniform.

It is also worth noting that although the thermal component 12 is depicted in this embodiment as having lateral edges, e.g., edges that run perpendicular to the backside surface of the chip 6, that are not co-extensive with but inside of lateral edges of the chip 6, other embodiments are not limited to this configuration. In some embodiments, the lateral edges of the thermal component 12 may be co-extensive with or outside of the lateral edges of the chip 6. Further, some lateral edges of the thermal component 12 may be co-extensive with or outside of corresponding lateral edges of the chip 6 while other lateral edges of the thermal component 12 are interior to the lateral edges of the chip 6.

In FIG. 4, the carrier substrate 2 and the lamination foil 4 are de-bonded from the reconfigured wafer level structure that comprises the chips 6, the thermal components 12, the adhesive films 10, and the molding compound 14. The de-bonding may be preformed by a heat treatment, a UV treatment, a de-bonding tool, the like, or a combination thereof.

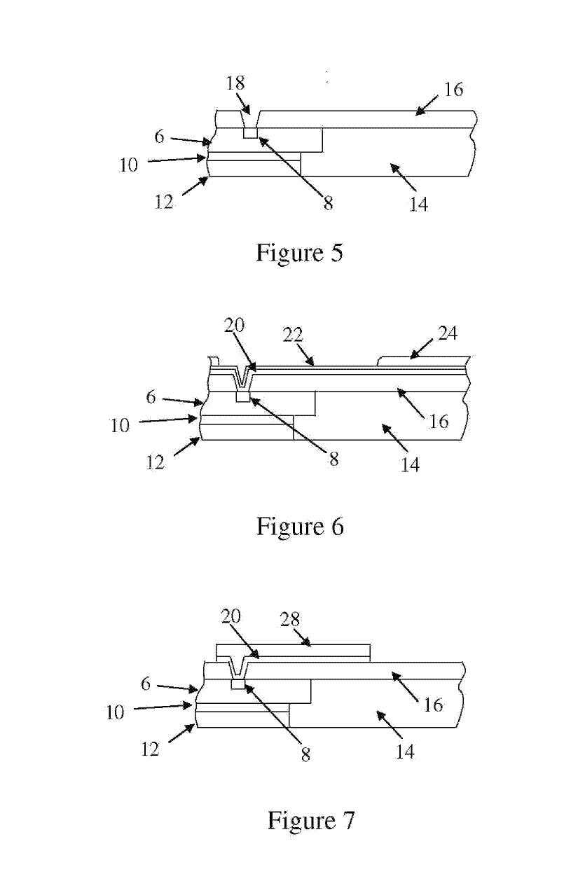

FIGS. 5 through 9 illustrate the formation of a redistribution layer (RDL) and a ball of a ball grid array. For ease and clarity of depiction, only a portion of the reconfigured wafer level structure is shown. A person having ordinary skill in the art will realize that the following steps may be applied the entire reconfigured wafer level structure.

In FIG. 5, a dielectric layer 16 is applied to the surface of the reconfigured wafer level structure that comprises the active surface of the chip 6. An opening 18 is the dielectric layer 16 is formed to expose the bond pad 8 of the chip 6. The dielectric layer 16 may be a polyimide, polybenzoxazole (PBO), the like, or a combination thereof. The dielectric layer 16 may be formed using a spin-on technique or other deposition method. The opening 18 may be formed using acceptable photolithography techniques and etching.

FIG. 6 illustrates the deposition of a barrier layer 20 and a seed layer 22 and the application and structuring of a plating resist 24. The barrier layer 20 is a thin conformal film formed over the dielectric layer 16 and on sidewalls of the opening 18. The barrier layer may be titanium nitride, tantalum nitride, tungsten nitride, titanium oxynitride, tantalum oxynitride, tungsten oxynitrde, titanium, the like, or a combination thereof. The barrier layer 20 may be deposited using methods such as chemical vapor deposition (CVD), plasma enhanced CVD (PECVD), low pressure CVD (LPCVD), physical vapor deposition (PVD), atomic layer deposition (ALD), sputtering, or other acceptable methods. The seed layer 22 is similarly a thin conformal layer formed over the barrier layer 20. The seed layer 22 may be the material used to form a redistribution interconnect such as copper, aluminum, tungsten, the like, or a combination thereof. The seed layer 22 may be formed by PVD, ALD, CVD, or other acceptable methods. The plating resist 24 may be formed by spin-on, lamination for a dry-film, or other acceptable methods. The plating resist 24 may be structured using acceptable photolithography techniques or other acceptable methods.

With reference to FIG. 7, a redistribution interconnect 28 is formed. The redistribution interconnect 28 may be copper, aluminum, tungsten, nickel, the like, or a combination thereof and may be formed using electroplating or other acceptable methods. The plating resist 24 is removed, for example, by stripping, and excess seed layer 22 and barrier layer 20 are removed, for example, by etching using the redistribution interconnect as a mask.

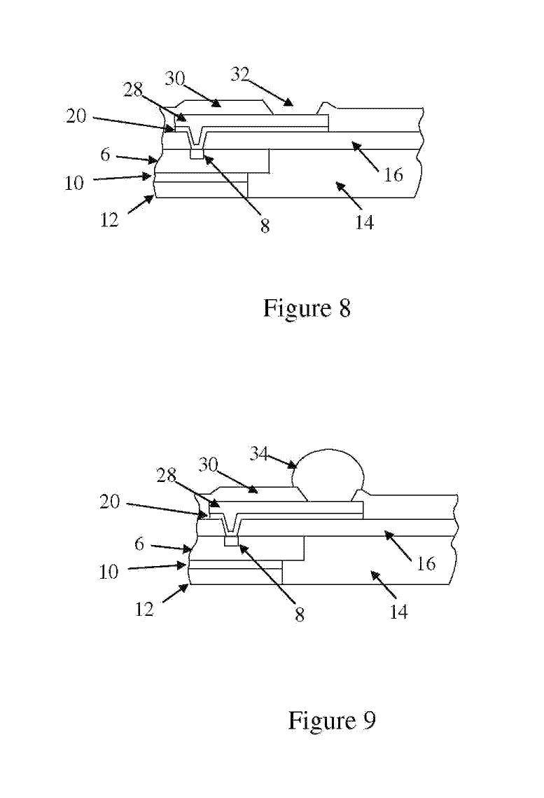

In FIG. 8, a solder stop 30 is applied and structured. The solder stop 30 may be a polyimide, polybenzoxazole (PBO), a solder-resist material, the like, or a combination thereof. The solder stop 30 may be formed using a spin-on technique or other deposition method. The solder stop 30 is structured to have an opening 32 to expose the redistribution interconnect 28. The opening 32 may be formed using acceptable photolithography techniques and etching.

Referring to FIG. 9, a solder ball 34 is formed in the opening 32 coupled to the redistribution interconnect 28. The solder ball 34 may also be a bump, column, pillar, the like, or a combination thereof and may be copper, tin, tin-silver, the like, or a combination thereof. The solder ball 34 may be formed using a reflow process or other acceptable method. As shown in FIG. 9, using a RDL structure, the solder ball 34 may be formed outside the lateral edge of the chip allowing for a fan-out of a ball grid array that may allow a greater area for the array compared to the active surface of the chip. The reconfigured wafer level structure is then sawed to singulate individual packages.

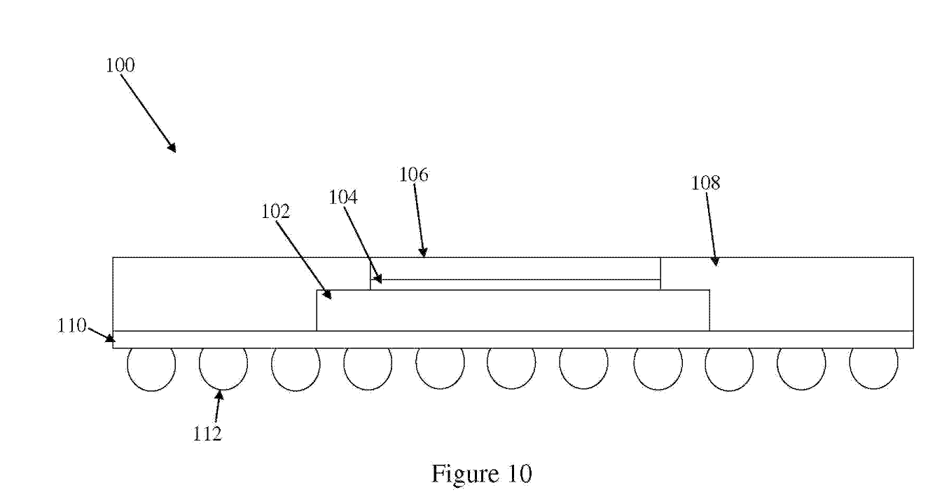

FIG. 10 depicts an integrated circuit package 100 according to an embodiment. The integrated circuit package 100 may be manufactured according to the embodiment described with respect to FIGS. 1 through 9. The package 100 includes a chip 102, an adhesive film 104 on the backside of the chip 102, a thermal component 106 adhered to the chip 102 by the adhesive film 104, molding compound 108 encapsulating the chip but exposing a surface of the thermal component 106, a redistribution layer (RDL) 110 on an active surface of the chip 102 and on a surface of the molding compound 108, and balls 112 of a ball grid array coupled to the RDL 110. The materials of these components may be the same or similar to corresponding components discussed with regard to FIGS. 1 through 9. The RDL 110 allows for fan-out of the ball grid array such that the area of the array is greater than the area of the active surface of the chip 102. The thickness of the molding compound 108 generally corresponds to the thickness of the combination of the chip 102, the adhesive film 104, and the thermal component 106. Thus, a surface of the thermal component 106 is exposed allowing for enhanced thermal dissipation of heat generated by the chip 102.

It is also worth noting that although the thermal component 106 is depicted in this embodiment as having lateral edges, e.g., edges that run perpendicular to the backside surface of the chip 102, that are not co-extensive with lateral edges of the chip 102, other embodiments are not limited to this configuration. In some embodiments, the lateral edges of the thermal component 106 may be co-extensive with or beyond of the lateral edges of the chip 102. Further, some lateral edges of the thermal component 106 may be co-extensive with or beyond of corresponding lateral edges of the chip 102 while other lateral edges of the thermal component 106 are interior to the lateral edges of the chip 102.

The integrated circuit package as disclosed may include enhanced thermal performance because the thermal component allows for increase dissipation of heat produced by a chip. Accordingly, the thermal dissipation efficiency of the package can be significantly improved and can be improved more with the addition of an external heat spreader. Embodiments may therefore be used in applications where heat dissipation kits are unavailable, such as in high performance hand-held products.

According to an embodiment, an integrated circuit package comprises a chip, a thermal component, and a molding compound. The chip comprises an active surface and a backside surface opposite the active surface. The thermal component is physically coupled to the backside surface of the chip. The molding compound encapsulates the chip, and an exposed surface of the thermal component is exposed through the molding compound.

According to another embodiment, an integrated circuit package comprises a chip, a heat dissipation element, and a molding. The chip has a first surface and a second surface. The first surface comprises bond pads, and the second surface is opposite the first surface. The heat dissipation element is on the second surface of the chip. The molding is on lateral edges of the chip, and the lateral edges of the chip extend from the first surface to the second surface of the chip. The molding also has an exterior surface through which an exposed surface of the heat dissipation element is exposed.

A further embodiment is a method for forming an integrated circuit package. The method comprises providing a thermal component on a backside surface of a chip; encapsulating the chip with a molding compound, a surface of the thermal component being uncovered by the molding compound; and forming a redistribution layer on an active surface of the chip and on the molding compound.

Although the present embodiments and their advantages have been described in detail, it should be understood that various changes, substitutions and alterations can be made herein without departing from the spirit and scope of the disclosure as defined by the appended claims. For example, it will be readily understood by those skilled in the art that differing numbers of interconnect layers may be used in the RDL while remaining within the scope of the present disclosure, even though only one is specifically described above. Further, different materials and processes for different components and steps may be used although not specifically identified herein. Also, the steps of the method to manufacture a package may be performed in any logical order, and embodiments are not limited to the order recited herein.

Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An integrated circuit package comprising:
a chip comprising an active surface and a backside surface opposite the active surface;
a thermal component physically coupled to the backside surface of the chip; and
a molding compound encapsulating the chip, an exposed surface of the thermal component being exposed through the molding compound.

2. The integrated circuit package of claim 1 further comprising an adhesive film between the chip and the thermal component, the adhesive film physically coupling the thermal component to the backside surface of the chip.

3. The integrated circuit package of claim 1, wherein the thermal component comprises a metal.

4. The integrated circuit package of claim 3, wherein the metal is selected from a group consisting of copper, nickel, aluminum, and a combination thereof.

5. The integrated circuit package of claim 1, wherein the thermal component comprises a semiconductor chip.

6. The integrated circuit package of claim 5, wherein the semiconductor chip comprises a same material that the chip includes.

7. The integrated circuit package of claim 5, wherein the semiconductor chip is a dummy chip.

8. The integrated circuit package of claim 1 further comprising a redistribution element on the active surface of the chip and on the molding compound.

9. The integrated circuit package of claim 8 further comprising a ball grid array electrically coupled to bond pads of the active surface of the chip through the redistribution element.

10. An integrated circuit package comprising:
a chip having a first surface and a second surface, the first surface comprising bond pads, the second surface being opposite the first surface;
a heat dissipation element on the second surface of the chip; and
a molding on lateral edges of the chip, the lateral edges of the chip extending from the first surface to the second surface of the chip, the molding having an exterior surface through which an exposed surface of the heat dissipation element is exposed.

11. The integrated circuit package of claim 10, wherein the exposed surface of the heat dissipation element is co-planar with the exterior surface of the molding.

12. The integrated circuit package of claim 10, wherein a lateral edge of the heat dissipation element is encapsulated by the molding.

13. The integrated circuit package of claim 10, wherein the heat dissipation element comprises a material selected from the group consisting essentially of a metal, a semiconductor, and a combination thereof.

14. The integrated circuit package of claim 10 further comprising:
a redistribution element on the molding and on the first surface of the chip; and
a ball grid array comprising solder balls electrically coupled to the bond pads through the redistribution element.

15. A method for forming an integrated circuit package, the method comprising:
providing a thermal component on a backside surface of a chip;
encapsulating the chip with a molding compound, a surface of the thermal component being uncovered by the molding compound; and
forming a redistribution layer on an active surface of the chip and on the molding compound.

16. The method of claim 15 further comprising:
adhering the active surface of the chip to a carrier substrate; and
removing the carrier substrate from the active surface of the chip before the forming the redistribution layer.

17. The method of claim 15, wherein the encapsulating the chip with the molding compound comprises using compression molding.

18. The method of claim 15 further comprising forming a ball grid array electrically coupled to the redistribution layer, the redistribution layer being electrically coupled to bond pads on the active surface of the chip.

19. The method of claim 15, wherein the thermal component is adhered to the backside surface of the chip.

20. The method of claim 15, wherein the thermal component comprises a metal, a dummy chip, or a combination thereof.
